(19) United States
(12) Patent Application Publication
(10) Pub. No.: US 2023/0045597 A1
(43) Pub. Date: Feb. 9, 2023

(54) METHODS AND APPARATUS FOR MINIMIZING VOIDS FOR CHIP ON WAFER COMPONENTS

(71) Applicant: Applied Materials, Inc., Santa Clara, CA (US)

(72) Inventors: Ying WANG, Singapore (SG); Guan Huei SEE, Singapore (SG)

(21) Appl. No.: 17/873,284

(22) Filed: Jul. 26, 2022

Related U.S. Application Data
(60) Provisional application No. 63/229,221, filed on Aug. 4, 2021.

(51) Int. Cl. H01L 21/463; H01L 21/02; H01L 21/68

(52) U.S. Cl. CPC H01L 21/463; H01L 21/02043; H01L 21/68

(57) ABSTRACT

Methods and apparatus for increasing a bonded area between an ultrathin die and a substrate. In some embodiments, the method may include cleaning the die and the substrate, placing the die on an upper surface of the substrate, compacting the die to the substrate using a downward force of at least one compacting roller on the die and the upper surface of the substrate to increase a bonded area between the die and the upper surface of the substrate, and annealing the die and the substrate. The compacting roller has a soft surface layer that engages with the die and the upper surface of the substrate. The soft surface layer has a Shore hardness of greater than approximately 30 and less than approximately 80. In some embodiments, the substrate and/or the compacting roller may rotate during contact with each other.

### FIELD

Embodiments of the present principles generally relate to semiconductor processing of semiconductor substrates.

### BACKGROUND

During back end of the line (BEOL) processing of wafers, circuits on wafers may be cut apart or diced and positioned onto a substrate to form larger circuits. A pick and place tool often uses vacuum to pick up the diced wafer portions and places the portions on the substrate. If the wafer and substrate have been properly cleaned, the diced wafer portions will bond to the substrate without using additional adhesives or other intermediate bonding techniques. The inventors, however, have observed that if the diced wafer portions are ultrathin, the vacuum of the pick and place tool may warp or cause a dimple in the ultrathin chips and cause voids or gaps between the bonding surfaces of the diced wafer portions and the substrate, leading to delamination of the ultrathin chips from the substrate.

Accordingly, the inventors have provided improved processes that minimizes voids between the bonding surfaces when chips are placed on the substrates, increasing bonding yields.

### SUMMARY

Methods and apparatus for minimizing voids in a chip on wafer bonding interface are provided herein.

In some embodiments, a method of bonding a die to a substrate may comprise receiving the substrate with the die placed on an upper surface of the substrate after cleaning and pick and place processes have completed and prior to annealing of the die and substrate, wherein the die has a thickness of less than approximately 60 microns and compacting the die to the substrate using a downward force on at least the die to increase a bonded area between the die and the upper surface of the substrate.

In some embodiments, the method may further include compacting the die to the substrate using the downward force of a compacting roller that contacts the die and the upper surface of the substrate, wherein the compacting roller has a soft surface layer that engages with the die and the upper surface of the substrate, the soft surface layer has a Shore 00 hardness of greater than approximately 30 and less than approximately 80, moving the substrate in a horizontal direction under the compacting roller, wherein the compacting roller is stationary in the horizontal direction and rotates when in contact with the die and the upper surface of the substrate, moving the compacting roller in a horizontal direction over the upper surface of the substrate while the substrate is stationary, wherein the compacting roller rotates when in contact with the die and upper surface of the substrate, wherein the compacting roller has a plurality of segments that rotate independent of other segments of the plurality of segments, wherein the compacting roller rotates lengthwise around a central perpendicular point of the compacting roller and rotates around a central axis of the compacting roller while in contact with the die and the upper surface of the substrate, compacting the die to the substrate using the downward force of a plurality of compacting rollers, wherein the plurality of compacting rollers each rotate independently of other ones of the plurality of compacting rollers, wherein each of the plurality of compacting rollers applies a different amount of downward force on the die and the upper surface of the substrate, compacting the die to the substrate using the downward force of a compacting disk that rotates in a horizontal plane as the compacting disk contacts the die and the upper surface of the substrate, wherein the compacting disk has undulations on a lower surface of the compacting disk that interfaces with the die and upper surface of the substrate, compacting the die to the substrate using the downward force of a compacting bar that slides across the die and the upper surface of the substrate, the compacting bar has a plurality of contact fingers that engage with the die and the upper surface of the substrate, compacting the die to the substrate using the downward force of a compacting stamp that provide direct vertical downward force on at least the die on the upper surface of the substrate, and/or wherein the compacting stamp has a rectangular or circular shape.

In some embodiments, a method of bonding a die to a substrate may comprise cleaning the die and the substrate, wherein the die has a thickness of less than approximately 60 microns, placing the die on an upper surface of the substrate, compacting the die to the substrate using a downward force of at least one compacting roller on the die and the upper surface of the substrate to increase a bonded area between the die and the upper surface of the substrate, and annealing the die and the substrate.

In some embodiments, the method may further include rolling the at least one compacting roller across the die and the upper surface of the substrate, rotating the at least one compacting roller or the substrate less than 360 degrees, and rolling the at least one compacting roller across the die and the upper surface of the substrate, and/or wherein the compacting roller has a soft surface layer that engages with the die and the upper surface of the substrate, the soft surface layer has a Shore 00 hardness of greater than approximately 30 and less than approximately 80.

In some embodiments, an apparatus for bonding a die to a substrate may comprise a substrate support with a substrate support surface configured to hold the substrate for processing, wherein the substrate support moves in a horizontal direction without rotating or rotates around a central axis perpendicular to the substrate support surface and at least one compacting roller that rotates around a longitudinal axis, wherein the at least one compacting roller has a resilient surface layer that engages with die having thicknesses of less than approximately 60 microns and an upper surface of the substrate, wherein the resilient surface layer has a Shore 00 hardness of greater than approximately 30 and less than approximately 80, and wherein the at least one compacting roller is configured to apply a total downward force of less than approximately 1.5 kilograms on the die to increase a bonded area between the die and the upper surface of the substrate.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of bonding an ultrathin die to a substrate in accordance with some embodiments of the present principles.

FIG. 2 depicts an isometric view of an ultrathin die picked and placed on a substrate in accordance with some embodiments of the present principles.

FIG. 3 depicts a top-down view of an acoustic micro image of a bonded area of a picked and placed ultrathin die on a substrate in accordance with some embodiments of the present principles.

FIG. 4 depicts an isometric view of a compacting apparatus with a single compacting roller in accordance with some embodiments of the present principles.

FIG. 5 depicts a top-down view of an acoustic micro image of a bonded area of an ultrathin die on a substrate after an enhanced bonding process in accordance with some embodiments of the present principles.

FIG. 6 depicts an isometric view of a compacting apparatus with a single configurable compacting roller in accordance with some embodiments of the present principles.

FIG. 7 depicts an isometric view of a compacting apparatus with multiple compacting rollers in accordance with some embodiments of the present principles.

FIG. 8 depicts an isometric view of a compacting apparatus with a single split compacting roller in accordance with some embodiments of the present principles.

FIG. 9 depicts an isometric view of a compacting apparatus with a single rotating disk in accordance with some embodiments of the present principles.

FIG. 10 depicts a cross-sectional view of a compacting apparatus with a single rotating disk in accordance with some embodiments of the present principles.

FIG. 11 depicts an isometric view of a compacting apparatus with a single compacting bar in accordance with some embodiments of the present principles.

FIG. 12 depicts a cross-sectional view of a compacting apparatus with a single compacting bar in accordance with some embodiments of the present principles.

FIG. 13 depicts a cross-sectional view of profiles for a compacting bar in accordance with some embodiments of the present principles.

FIG. 14 depicts an isometric view of a compacting apparatus with one or more stamps in accordance with some embodiments of the present principles.

FIG. 15 depicts a top-down view of a substrate and indicates directional paths across the substrate for a compacting apparatus in accordance with some embodiments of the present principles.

FIG. 16 depicts a cross-sectional view of an enhanced bonding system in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide improved chip on wafer (CoW) direct bonding of ultrathin die by using a mechanical force during a post-bonding stage before annealing. Ultrathin die (denoted as die with a thickness of less than or equal to 60 microns) are prone to warping during CoW pick and place (P&P) and bonding processes due to the structural vulnerability of the ultrathin die. Such die warping may be translated to macroscopic voids at the die-to-substrate interface. Using current technologies, void-free bonding of ultrathin die to substrates requires costly and sophisticated state-of-the-art bonders and bond-head designs along with stringent process control. The methods and apparatus of the present principles provide reliable and cost-effective processes to reduce voids of ultrathin die at the post-bond stage.

Current technologies typically address bonding issues through bond head and flipper collect vacuum hole design and/or ejector pin array arrangement and/or bonding conditions optimization during bonding, followed by thermal annealing. The present principles introduce a new additional compacting process in between traditional bonding and annealing steps to improve bonding performance by producing smaller voids in the die-to-substrate interfaces leading to enhanced bonding yields. In some embodiments, a soft compacting roller rolls over the die-attached substrate (e.g., a single long roller across wafer and/or multiple/configurable compacting rollers) to promote contact bonding of the ultrathin die to the substrate. In some embodiments, a soft compacting stamp may be used on the die-attached substrate to also promote contact bonding of the ultrathin die to the substrate.

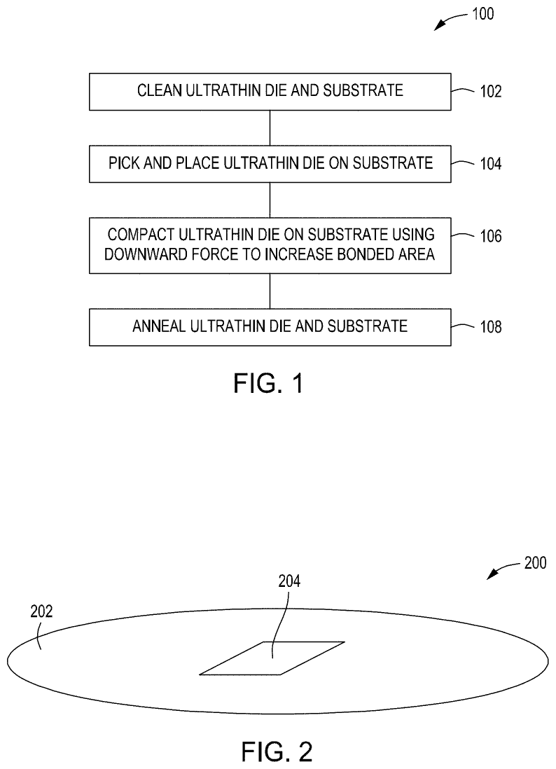

During discussion of the methods of the present principles, references to FIGS. 2-15 may be used to illustrate different aspects. FIG. 1 is a method 100 of bonding an ultrathin die 204 to a substrate 202 in accordance with some embodiments (see, e.g., FIG. 2). In block 102, both the ultrathin die 204 and the substrate 202 are cleaned to enhance bonding between the ultrathin die 204 and the substrate 202. If the surfaces to be bonded are clean, the dielectric surfaces will attract and bond at an atomic level. In block 104, the ultrathin die 204 is picked and placed on the substrate 202 as shown in a view 200 of FIG. 2. As used herein, picking and placing the ultrathin die 204 on the substrate 202 causes the ultrathin die 204 to bond to the substrate 202 (i.e., a bonding or hybrid bonding process has occurred).

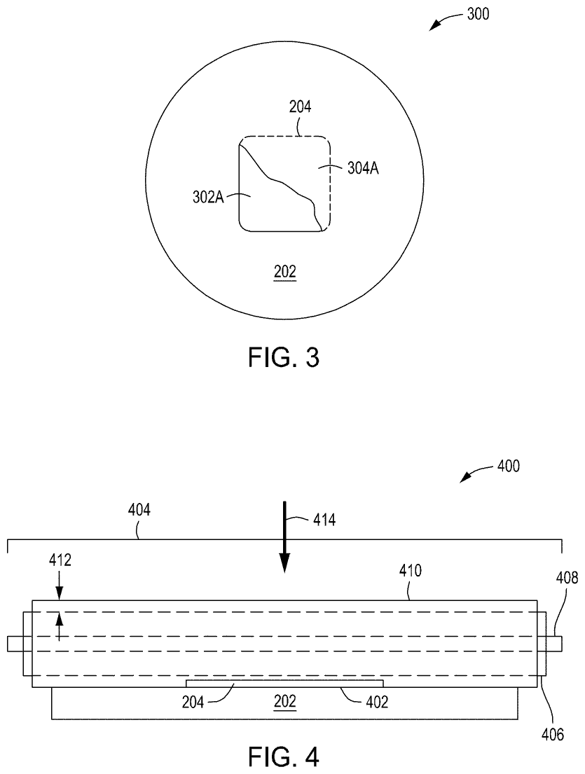

FIG. 3 depicts a top-down view 300 of an acoustic micro image of a first bonded area 302A of the picked and placed ultrathin die 204 on the substrate 202 in accordance with some embodiments. As shown in an example in FIG. 3, the first bonded area 302A is only approximately 50% of the total area of the interface area between the ultrathin die 204 and the substrate 202 (the total interface area is essentially the outline of the ultrathin die 204). In the example, almost 50% of the area of the total interface area between the ultrathin die 204 is a first unbonded area 304A. The partial bonding may occur due to air trapped between the ultrathin die 204 and the substrate 202 due to pick and place caused deformities in the ultrathin die 204. A typical bond head uses vacuum to lift the ultrathin die 204 during pick and place procedures. The vacuum may distort the ultrathin die 204 as the ultrathin die 204 is not rigid enough to withstand the vacuum force exerted on the ultrathin die 204 by the bond head. The ultrathin die 204 may become warped during the process such as a concave warp that allows air to be trapped between the ultrathin die 204 and the substrate 202, leading to partial bonding of the ultrathin die 204 to the substrate 202.

In block 106, the ultrathin die 204 is compacted on the substrate 202 using a downward force to increase the first bonded area 302A. FIG. 4 depicts an isometric view 400 of a compacting apparatus with a single compacting roller 404 in accordance with some embodiments. As described herein, the compacting apparatus includes different structures. For the sake of brevity, a single compacting roller structure is used as an initial example of a compacting apparatus for the method 100 and is not meant to be limiting. To increase the bonded area 302A of the interface 402 between the ultrathin die 204 and the substrate 202, in the example, the single compacting roller 404 is rolled over the ultrathin die 204 and the substrate 202 while a downward force 414 is applied to the single compacting roller 404. The downward force 414 is a controlled downward force that may be adjusted based on ultrathin die parameters such as, but not limited to, area of the ultrathin die, thickness of the ultrathin die, and/or composition (materials) of the ultrathin die and the like and/or parameters of the compacting apparatus such as, but not limited to, total contact area, ultrathin die contact area, and/or substrate contact area and the like. The downward force 414 should be sufficient to remove voids or trapped air from the interface but less than a force that would crack the ultrathin die. In some embodiments, the applied force may be from approximately 0.3 kg to approximately 1.5 kg. In some embodiments, the rotational speed of the compacting roller may be varied to allow more or less dwell time on different areas of the ultrathin die 204 to ensure proper and complete bonding. A longer dwell time allows more time for air to escape and close the void.

In some embodiments, the single compacting roller 404 includes an inner support structure 406 and may also include an optional inner support rod 408 to assist in increasing the rigidity of the single compacting roller 404 when force is applied. The single compacting roller 404 also includes a surface layer 410 with a thickness 412. In some embodiments, the surface layer 410 is composed of a material with a Shore 00 hardness of greater than approximately 30 and less than approximately 80. The hardness allows the surface layer 410 to be ‘soft’ and prevents damage to the ultrathin die 204 and/or the substrate 202. The surface layer 410 is also resilient. The resiliency of the surface layer 410 allows the surface layer 410 to account for thickness variations and/or deformities such as warping (e.g., caused by the bonder head) of the ultrathin die 204 as the single compacting roller 404 rolls over the surface of the ultrathin die 204 and the substrate 202 and rebound before encountering the next ultrathin die on the substrate with multiple dies. Because the single compacting roller 404 makes contact with the upper surface of the ultrathin die 204 and the upper surface of the substrate 202, the downward force is spread across both surfaces and prevents damage to the ultrathin die 204. The rolling action of the single compacting roller 404 also prevents any tearing of the ultrathin die as the single compacting roller 404 moves across the substrate 202. The thickness 412 of the surface layer 410 is greater than the thickness of the ultrathin die 204 (>60 μm). The thickness 412 of the surface layer 410 prevents the inner structure 406 from exerting too much localized downward force and damaging the ultrathin die 204.

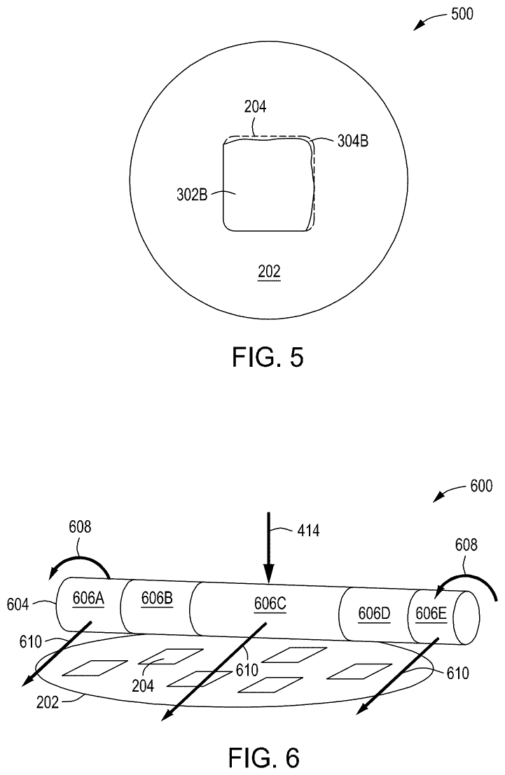

FIG. 5 depicts a top-down view 500 of an acoustic micro image of a second bonded area 302B of the ultrathin die 204 on the substrate 202 after the enhanced compacting bonding process (block 106) such as in method 100 is performed. When compared to the first bonded area 302A of FIG. 3, the second bonded area 302B is substantially larger (e.g., almost approximately 100% of the total interface area between the ultrathin die 204 and the substrate 202). Likewise, the second unbonded area 304B is substantially smaller than the first unbonded area 304A of FIG. 3. The compacting of the ultrathin die to the substrate using the downward force of the compacting apparatus substantially improves the bond of the ultrathin die 204 to the substrate 202 without damaging the ultrathin die. In block 108, the ultrathin die 204 and the substrate 202 are annealed to further enhance the bond between the ultrathin die 204 and the substrate 202. The post bond anneal serves two purposes. One is to strengthen the bonding of the dielectric and the second one is to promote the bonding of interconnect material, such as copper, by promoting copper grain growth and bridging the interconnect material between the two interfaces to make electrical connections. Incomplete bonding of the ultrathin die 204 to the substrate 202 leaves voids that are too great for the interconnect material to bridge over, leading to defective chips with open electrical connections. In some embodiments, the anneal process has a temperature of approximately 200 degrees Celsius to approximately 350 degrees Celsius. The higher the temperature, the larger distance that may be bridged for electrical contacts. If the temperature is too high, low thermal budget components such as memory and other semiconductor structures may be damaged.

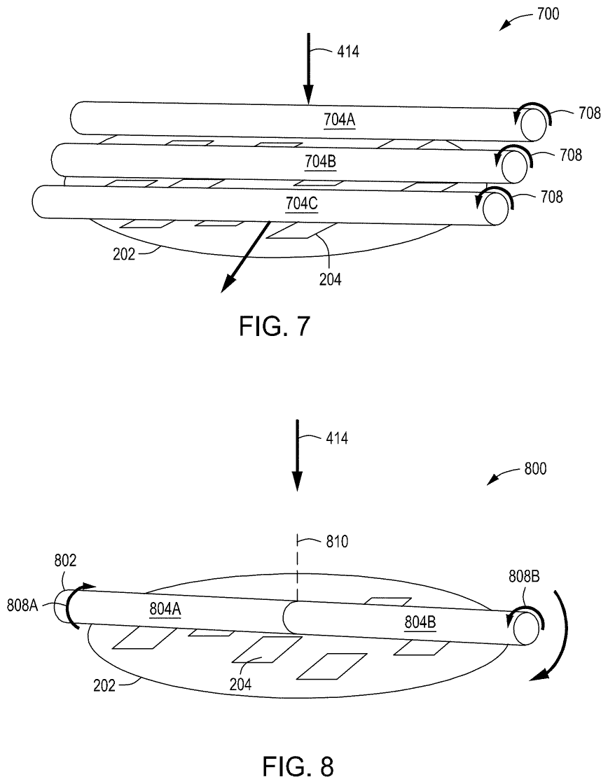

The compacting apparatus of the present principles may include different structures that may be used in the method 100 to compact the ultrathin die to the substrate to increase bonding yields. For example, FIG. 6 depicts an isometric view 600 of a compacting apparatus with a single configurable compacting roller 604 in accordance with some embodiments. The single configurable compacting roller 604 includes two or more independent segments such as, for example, segments 606A-606E. Each segment rotates 608 independently of the other segments. In addition, each of the segments 606A-606E may also use materials in the surface layers that have different hardness and/or different thicknesses. The variation in hardness can be used to apply more or less downward force on different areas of a substrate as the single configurable compacting roller 604 rolls across 610 the substrate. Similarly, different thicknesses of the surface layer may be used to account for thinner or thicker ultrathin dies used in different areas of the substrate. The configurability allows for increased flexibility for use in semiconductor manufacturing. FIG. 7 depicts an isometric view 700 of a compacting apparatus with multiple compacting rollers 704A-704C in accordance with some embodiments. The multiple compacting rollers 704A-704C each rotate 708 independently of the other compacting rollers. The multiple compacting rollers 704A-7040 allow multiple ‘roller passes’ to be made across the substrate 202 each time the compacting apparatus is moved across the substrate 202, saving time while increasing the bonded area of the ultrathin die 204 and the substrate 202.

FIG. 8 depicts an isometric view 800 of a compacting apparatus with a single split compacting roller 802 in accordance with some embodiments. The single split compacting roller 802 has a first compacting roller 804A with a first rotating direction 808A and a second compacting roller 804B with a second rotating direction 808B. The single split compacting roller 802 rotates about a central axis 810. Each half of the single split compacting roller 802 is allowed to rotate independently as a downward force is applied while the single split compacting roller 802 rolls over the ultrathin die 204 and the substrate 202. In some embodiments, the single split compacting roller 802 rotates about the central axis 810. In some embodiments, the substrate 202 with the ultrathin die 804 is rotated. In some embodiments, the substrate 202 and the single split compacting roller 802 rotate in opposite directions about the central axis 810.

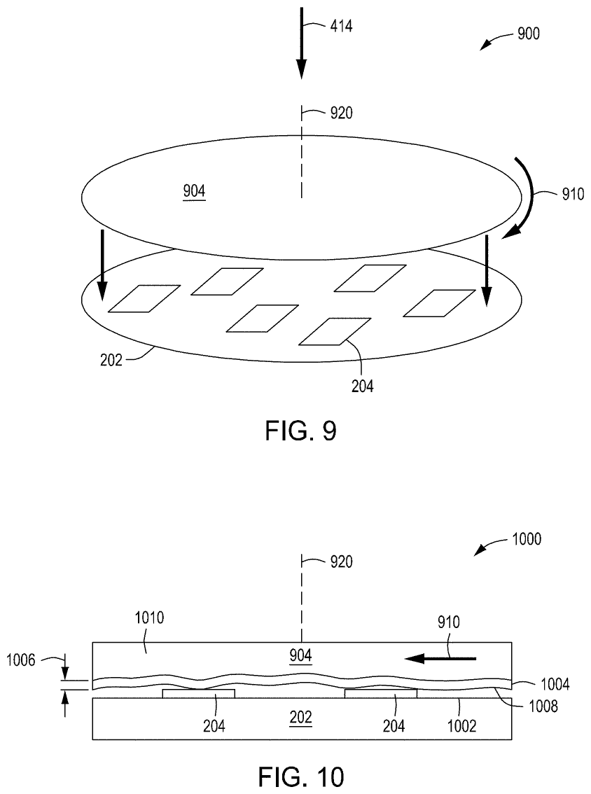

FIG. 9 depicts an isometric view 900 of a compacting apparatus with a single rotating disk 904 in accordance with some embodiments. In some embodiments, the single rotating disk 904 rotates 910 about a central axis 920 and is lowered down until contact is made with the substrate 202 with ultrathin die 204, applying a downward force as the single rotating disk 904 rotates. In some embodiments, the substrate 202 rotates about a central axis 920 and is raised upward until contact is made with the single rotating disk 904, applying an upward force on the substrate 902 as the substrate rotates. FIG. 10 depicts a cross-sectional view 1000 of the compacting apparatus with the single rotating disk 904 in accordance with some embodiments. The single rotating disk 904 has a surface layer 1004 with a thickness 1006. In some embodiments, the thickness 1006 may be greater than 60 μm. If the surface layer 1004 is also in contact with the uppermost surface 1002 of the substrate 202, the thickness 1006 may be greater than 60 μm to allow the surface layer 1004 to protect the ultrathin die 204 from a harder underlying support surface (supporting structure 1010) of the single rotating disk 904. In some embodiments, the thickness 1006 may be less than 60 μm. If the single rotating disk 904 is set to a height above the uppermost surface 1002 of the substrate 202 such that the surface layer 1004 only contacts the ultrathin die 204, the thickness 1006 of the surface layer 1004 may be less than 60 μm. In some embodiments, the surface layer 1004 comes into contact with the upper surfaces of the ultrathin die 204 and may also come into contact with the upper surface of the substrate 202 as either the single rotating disk 904 rotates about the central axis 920 and/or the substrate 202 rotates about the central axis 920. In some embodiments (not shown), the single rotating disk 904 may be larger than the substrate 202 in diameter and rotate about a second central axis (not shown).

In some embodiments, the surface layer 1004 is composed of a material with a Shore 00 hardness of greater than approximately 30 and less than approximately 80. The hardness allows the surface layer 1004 to be ‘soft’ and prevents damage to the ultrathin die 204 and/or the substrate 202. The surface layer 1004 is also resilient. The resiliency of the surface layer 1004 allows the surface layer 1004 to account for thickness variations and/or deformities such as warping (e.g., caused by the bonder head) of the ultrathin die 204 as the single rotating disk 904 moves over the surface of the ultrathin die 204 and the substrate 202 and rebound before encountering the next ultrathin die on a substrate with multiple dies. In some embodiments, the surface layer 1004 has undulations on at least a lower surface 1008. The undulations allow for the surface layer 1004 to smoothly pass over the upper surface of the ultrathin die 204 without catching an edge of the ultrathin die 204. The undulations permit pressure to be applied to the ultrathin die 204 without the risk of tearing the ultrathin die 204 and also allow pressure to be applied to any concave areas that may have occurred due to pick and place processes. In some embodiments, the thickness 1006 of the surface layer 1004 is greater than the thickness of the ultrathin die 204 (>60 μm). The thickness 1006 of the surface layer 1004 prevents the supporting structure 1010 that supplies a backing to the surface layer 1004 from exerting too much localized downward and rotational force and damaging the ultrathin die 204.

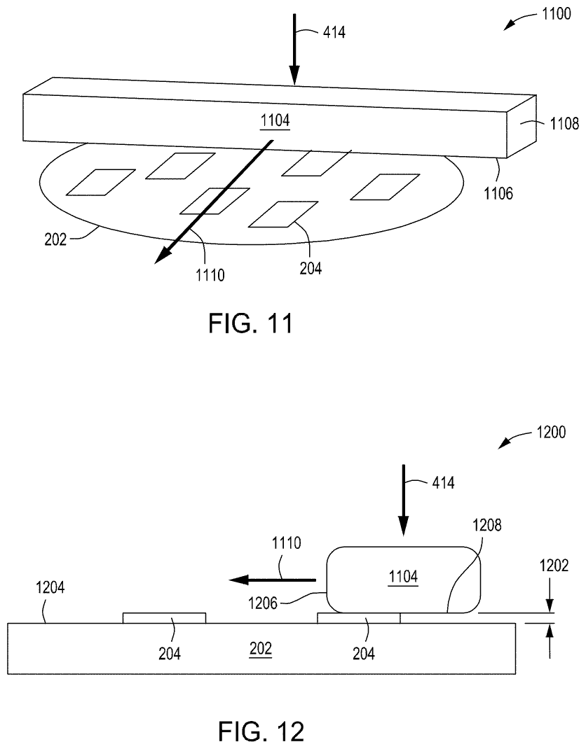

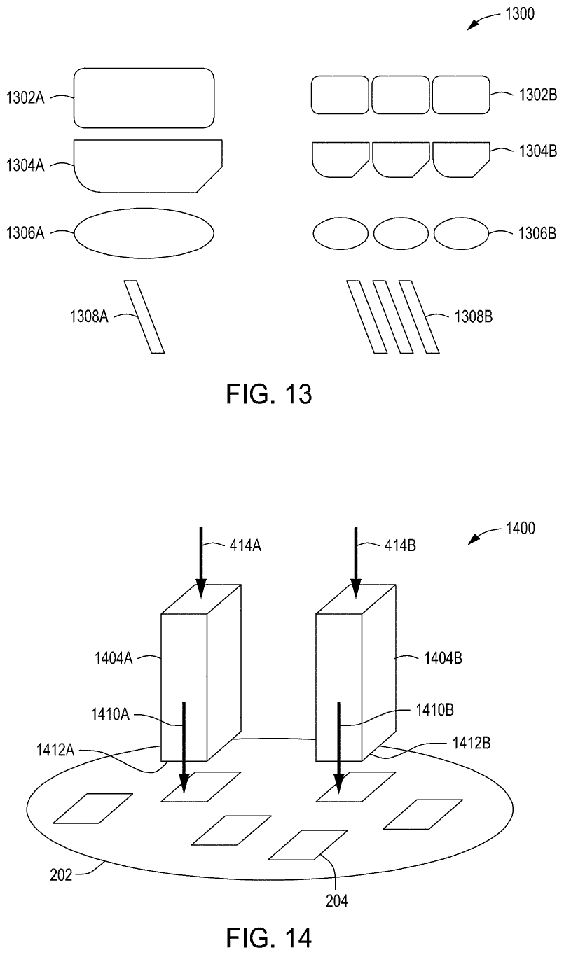

FIG. 11 depicts an isometric view 1100 of a compacting apparatus with a single compacting bar 1104 in accordance with some embodiments. Although only a single compacting bar 1104 is depicted, the compacting apparatus may also include multiple compacting bars (not shown) that allow for multiple engagements with the ultrathin die 204 in a single pass over the substrate 202 by the compacting apparatus similar to the multiple compacting rollers described above and are not further described herein for the sake of brevity but may incorporate all or some of the aspects of the single compacting bar 1104. The single compacting bar 1104 may apply a downward force 414 and a shearing force 1110 on the ultrathin die 204 and the substrate 202. The single compacting bar 1104 has a compacting surface 1106 and a profile 1108. FIG. 12 depicts cross-sectional view 1200 of a compacting apparatus with the single compacting bar 1104 in accordance with some embodiments. In some embodiments, the single compacting bar 1104 may apply downward force 414 and the shearing force 1110 across the ultrathin die 204 at a height 1202 above an upper surface 1204 of the substrate 202. The height 1202 can be adjusted based on thicknesses of the ultrathin die 204 to avoid damage such as tearing of the ultrathin die 204. In some embodiments, the single compacting bar 1104 may have a surface layer on a leading edge 1206 and/or on a lowermost surface 1208 of the single compacting bar 1104 similar to the surface layers described above to avoid damaging the ultrathin die 204. FIG. 13 depicts cross-sectional views 1300 of profiles such as profile 1108 for a compacting bar such as the single compacting bar 1104 or for multiple compacting bars in accordance with some embodiments. Single compacting bar profiles 1302A-1308A and multiple compacting bar profiles 1302B-1308B are depicted may be used with some embodiments of the compacting apparatus.

FIG. 14 depicts an isometric view 1400 of a compacting apparatus with one or more stamps in accordance with some embodiments. In some embodiments, a first stamp 1404A may apply a first downward force 414A on one or more of the ultrathin die 204. In some embodiments, a second stamp 1404B may apply a second downward force 414B on one or more of the ultrathin die 204. In some embodiments, the first downward force 414A and the second downward force 414B may be equal or different. In some embodiments, the first stamp 1404A may apply the first downward force 414A in a downward direction 1410A on a first ultrathin die, and the second stamp 1404B may apply the second downward force 414B on a second ultrathin die in a downward direction 1410B. In some embodiments, the first ultrathin die and the second ultrathin die may be the same ultrathin die to enhance the bonding between the ultrathin die and the substrate. In some embodiments, the lowermost surfaces 1412A, 1412B may have a surface layer such as the surface layers described above to prevent damage to the ultrathin die as the downward force is applied. In some embodiments, the surface layer of a stamp may be harder in a center of the stamp and become more resilient towards the edges to allow air to be forced out first at the center of the ultrathin die and the propagate to the edges of the ultrathin die to be released into the environment. The more resilient edges prevent the edges of the ultrathin die from sealing off immediately while the center of the die expels the air. The shape of the stamps may be rectangular and/or circular and or other shapes and the like. The stamps may also be larger with a larger stamping surface that may encompass a plurality of ultrathin die. The stamps have the advantages of permitting precise forces to be used and also exact placement of the force on areas of the substrate. An additional benefit of multiple stamps is the ability to have different stamps with different forces available for enhancing bonding of the ultrathin die. The substrate may also be moved horizontally in any direction to allow a stationary stamp to apply downward force on any area of the substrate.

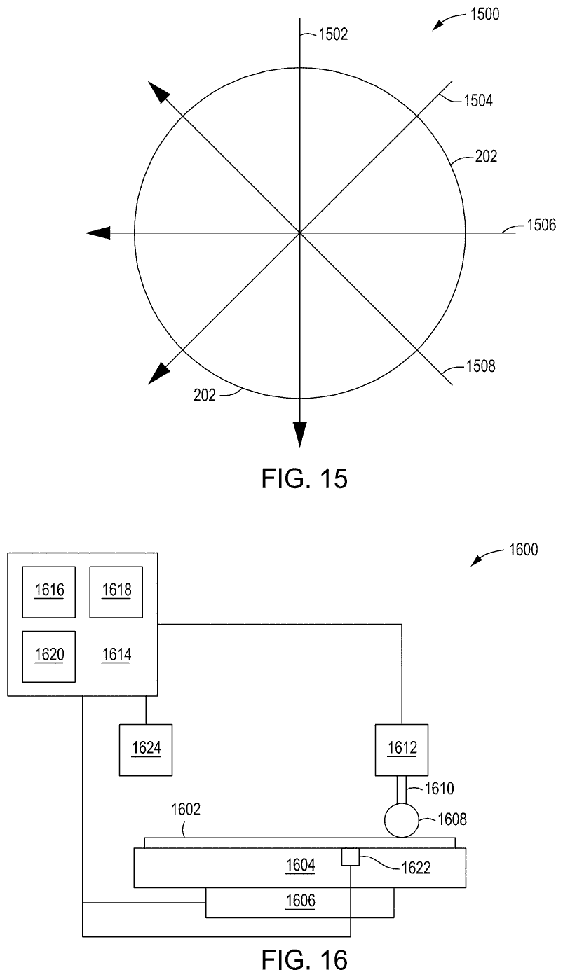

FIG. 15 depicts a top-down view 1500 of the substrate 202 and indicates directional paths 1502-1508 across the substrate 202 for a compacting apparatus in accordance with some embodiments. In the example, which is not meant to be limiting, the directional paths 1502-1508 across the substrate 202 are at increments of 45 degree angles. Other angle increments may be used in order to ensure bonding of the ultrathin die to the substrate 202. In some embodiments, the compacting apparatus may be rotated a number of degrees prior to each pass. In some embodiments, the compacting apparatus may be stationary and the substrate may be rotated a number of degrees prior to each pass. Although the directional paths 1502-1508 indicate a single direction, the compacting apparatus may be moved back and forth across the substrate one or more times at each increment to ensure proper bonding of the ultrathin die to the substrate.

FIG. 16 depicts a cross-sectional view of a bonding system 1600 in accordance with some embodiments. The bonding system 1600 includes a substrate support 1604 to support a substrate 1602 for processing. A first motor 1606 is operatively connected to the substrate support 1604 to provide movement of the substrate support 1604 and subsequently the substrate 1602. In some embodiments, the first motor 1606 may be optional. The movement of the substrate support 1604 may be vertical (up and down), horizontal in one or more directions (side to side), and/or rotational. The bonding system 1600 also includes a compacting apparatus 1608. The compacting apparatus 1608 may include one or more of the embodiments described above. The compacting apparatus 1608 operatively interfaces with a connecting structure 1610 that operatively interfaces with a second motor 1612. The second motor 1612 provides movement of the compacting apparatus 1608. In some embodiments, the second motor 1612 may be optional. The movement of the compacting apparatus 1608 may be vertical (up and down), horizontal in one or more directions (side to side), and/or rotational. The first motor 1606 and the second motor 1612 are operatively connected to a controller 1614. In some embodiments, the bonding system 1600 may also include a first sensor 1624 and/or a second sensor 1622.

The first sensor 1624 may be positioned above the substrate 1602 and be enabled to determine a degree of bonding between an ultrathin die and the substrate 1602. The second sensor 1622 may be positioned in the substrate support 1604 and be enabled to determine a degree of bonding between an ultrathin die and the substrate 1602. In some embodiments, the first sensor 1624 and/or the second sensor 1622 may be, but not limited to, an optical based sensor such as an infrared based sensor and/or an ultraviolet based sensor and the like. The controller 1614 may adjust enhanced bonding processes through control of forces applied by the compacting apparatus 1608 and/or by raising of the substrate support 1604 with the first motor 1606 into the compacting apparatus 1608. The controller 1614 may adjust the enhanced bonding processes through control of the direction of the movements and/or the speed of the movements of the compacting apparatus 1608 and/or the substrate support 1604. The controller 1614 may adjust the enhanced bonding processes through control of the number of passes of the compacting apparatus 1608 and/or the substrate support 1604. In some embodiments, recipes may be used by the controller 1614 that are executed based on the type, size, quantity, and/or thickness of the ultrathin die placed on a substrate. The controller 1614 may also determine which type of compacting apparatus is used based on the type, size, quantity, and/or thickness of the ultrathin die placed on a substrate.

The controller 1614 controls the operation of the bonding system 1600 using a direct control or alternatively, by controlling computers (or controllers) associated apparatus of the bonding system 1600. In operation, the controller 1614 enables data collection and feedback from the apparatus to optimize performance of the bonding system 1600. The controller 1614 generally includes a Central Processing Unit (CPU) 1616, a memory 1618, and a support circuit 1620. The CPU 1616 may be any form of a general-purpose computer processor that can be used in an industrial setting. The support circuit 1620 is conventionally coupled to the CPU 1616 and may comprise a cache, clock circuits, input/output subsystems, power supplies, and the like. Software routines, such as a method as described above may be stored in the memory 1618 and, when executed by the CPU 1616, transform the CPU 1616 into a specific purpose computer (controller 1614). The software routines may also be stored and/or executed by a second controller (not shown) that is located remotely from the bonding system 1600.

The memory 1618 is in the form of computer-readable storage media that contains instructions, when executed by the CPU 1616, to facilitate the operation of the semiconductor processes and equipment. The instructions in the memory 1618 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of bonding a die to a substrate, comprising:
receiving the substrate with the die placed on an upper surface of the substrate after cleaning and pick and place processes have completed and prior to annealing of the die and substrate, wherein the die has a thickness of less than approximately 60 microns; and
compacting the die to the substrate using a downward force on at least the die to increase a bonded area between the die and the upper surface of the substrate.

2. The method of claim 1, further comprising:
compacting the die to the substrate using the downward force of a compacting roller that contacts the die and the upper surface of the substrate.

3. The method of claim 2, wherein the compacting roller has a soft surface layer that engages with the die and the upper surface of the substrate, the soft surface layer has a Shore 00 hardness of greater than approximately 30 and less than approximately 80.

4. The method of claim 3, further comprising:
moving the substrate in a horizontal direction under the compacting roller, wherein the compacting roller is stationary in the horizontal direction and rotates when in contact with the die and the upper surface of the substrate.

5. The method of claim 3, further comprising:
moving the compacting roller in a horizontal direction over the upper surface of the substrate while the substrate is stationary, wherein the compacting roller rotates when in contact with the die and upper surface of the substrate.

6. The method of claim 2, wherein the compacting roller has a plurality of segments that rotate independent of other segments of the plurality of segments.

7. The method of claim 2, wherein the compacting roller rotates lengthwise around a central perpendicular point of the compacting roller and rotates around a central axis of the compacting roller while in contact with the die and the upper surface of the substrate.

8. The method of claim 1, further comprising:
compacting the die to the substrate using the downward force of a plurality of compacting rollers.

9. The method of claim 8, wherein the plurality of compacting rollers each rotate independently of other ones of the plurality of compacting rollers.

10. The method of claim 8, wherein each of the plurality of compacting rollers applies a different amount of downward force on the die and the upper surface of the substrate.

11. The method of claim 1, further comprising:
compacting the die to the substrate using the downward force of a compacting disk that rotates in a horizontal plane as the compacting disk contacts the die and the upper surface of the substrate.

12. The method of claim 11, wherein the compacting disk has undulations on a lower surface of the compacting disk that interfaces with the die and upper surface of the substrate.

13. The method of claim 1, further comprising:
compacting the die to the substrate using the downward force of a compacting bar that slides across the die and the upper surface of the substrate.

14. The method of claim 13, wherein the compacting bar has a plurality of contact fingers that engage with the die and the upper surface of the substrate.

15. The method of claim 1, further comprising:
compacting the die to the substrate using the downward force of a compacting stamp that provide direct vertical downward force on at least the die on the upper surface of the substrate.

16. The method of claim 15, wherein the compacting stamp has a rectangular or circular shape.

17. A method of bonding a die to a substrate, comprising:
cleaning the die and the substrate, wherein the die has a thickness of less than approximately 60 microns;
placing the die on an upper surface of the substrate;
compacting the die to the substrate using a downward force of at least one compacting roller on the die and the upper surface of the substrate to increase a bonded area between the die and the upper surface of the substrate; and
annealing the die and the substrate.

18. The method of claim 17, further comprising:
rolling the at least one compacting roller across the die and the upper surface of the substrate;
rotating the at least one compacting roller or the substrate less than 360 degrees; and
rolling the at least one compacting roller across the die and the upper surface of the substrate.

19. The method of claim 17, wherein the compacting roller has a soft surface layer that engages with the die and the upper surface of the substrate, the soft surface layer has a Shore 00 hardness of greater than approximately 30 and less than approximately 80.

20. An apparatus for bonding a die to a substrate, comprising:
a substrate support with a substrate support surface configured to hold the substrate for processing, wherein the substrate support moves in a horizontal direction without rotating or rotates around a central axis perpendicular to the substrate support surface; and
at least one compacting roller that rotates around a longitudinal axis, wherein the at least one compacting roller has a resilient surface layer that engages with die having thicknesses of less than approximately 60 microns and an upper surface of the substrate, wherein the resilient surface layer has a Shore 00 hardness of greater than approximately 30 and less than approximately 80, and wherein the at least one compacting roller is configured to apply a total downward force of less than approximately 1.5 kilograms on the die to increase a bonded area between the die and the upper surface of the substrate.
